(19) United States
(12) Patent Application Publication
(10) Pub. No.: US 2026/0369308 A1
(43) Pub. Date: Nov. 19, 2026

(54) MEMORY DEVICES AND METHODS OF MANUFACTURING THEREOF

(71) Applicant: Taiwan Semiconductor Manufacturing Company, Ltd., Hsinchu (TW)

(72) Inventor: Masayoshi Nakayama, Hsinchu City (TW)

(73) Assignee: Taiwan Semiconductor Manufacturing Company, Ltd., Hsinchu (TW)

(21) Appl. No.: 19/741,840

(22) Filed: Jul. 14, 2026

Related U.S. Application Data
(63) Continuation of application No. 19/049,429, filed on Feb. 10, 2025.
(60) Provisional application No. 63/712,003, filed on Oct. 25, 2024.

(51) Int. Cl. G11C 5/06; G11C 13/00

(52) U.S. Cl. CPC G11C 5/063; G11C 13/0028; G11C 13/004; G11C 13/0069

(57) ABSTRACT

A memory circuit includes a memory array including memory cells coupled to a word line and a driver circuit coupled to the memory cells through the word line. The driver circuit includes a p-type transistor coupled between the word line and a switchable voltage selected among first, second, and third supply voltages, an inverter having an input configured to receive a logically inverted version of a selection signal provided at a first logic state to assert the word line and an output configured to provide an intermediate signal, and a first n-type transistor having a gate terminal, a first source/drain terminal, and a second source/drain terminal. The gate terminal is configured to receive a control signal switching between the first supply voltage and a fourth supply voltage, the first source/drain terminal is connected to the output of the inverter, and the second source/drain terminal is connected to the word line.

### CROSS-REFERENCE TO RELATED APPLICATIONS

This application is a continuation of U.S. patent application Ser. No. 19/049,429, filed Feb. 10, 2025, which claims priority to and the benefit of U.S. Provisional Application No. 63/712,003, filed Oct. 25, 2024, the entire contents of which are incorporated herein by reference for all purposes.

### BACKGROUND

The semiconductor integrated circuit (IC) industry has experienced exponential growth. As ICs continue to scale down, more devices are integrated into the single chip. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of an example memory device (or circuit), in accordance with some embodiments.

FIG. 2 illustrates a block diagram of an example memory circuit, in accordance with some embodiments.

FIG. 3 illustrates a circuit diagram of an example memory circuit that can be included in the memory circuit of FIG. 1, in accordance with some embodiments.

FIG. 4 and FIG. 5 illustrate example waveforms associated with a memory circuit, in accordance with some embodiments.

FIG. 6 illustrates a circuit diagram of an example memory circuit that can be included in the memory circuit of FIG. 1, in accordance with some embodiments.

FIG. 7 and FIG. 8 illustrate example waveforms associated with a memory circuit, in accordance with some embodiments.

FIG. 9 illustrates a circuit diagram of an example memory circuit that can be included in the memory circuit of FIG. 1, in accordance with some embodiments.

FIG. 10 and FIG. 11 illustrate example waveforms associated with a memory circuit, in accordance with some embodiments.

FIG. 12 illustrates a circuit diagram of an example memory circuit that can be included in the memory circuit of FIG. 1, in accordance with some embodiments.

FIG. 13 and FIG. 14 illustrate example waveforms associated with a memory circuit, in accordance with some embodiments.

FIG. 15 illustrates a circuit diagram of an example memory circuit that can be included in the memory circuit of FIG. 1, in accordance with some embodiments.

FIG. 16 illustrates a flow chart of an example method for operating a memory circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In general, a word line driver controls the activation of the word line (WL) in a memory device (e.g., a resistive switching memory) by supplying appropriate voltage levels for read and write operations. During a write operation, the word line driver provides a higher voltage to the word line, while during a read operation, it supplies a lower voltage. In the memory device, the word line voltage is generally higher during write operations compared to read operations. Consequently, the word line driver switches between these two voltage levels, using a high-voltage transistor to handle the increased voltage during write operations. Typically, word line drivers include a high-voltage transistor and voltage switches to select the appropriate power supply based on the operation mode-either read or write. However, a significant issue is that the drive capability of the high-voltage transistor is limited, especially at low voltages during read operations. To achieve high-speed read operations, some word line drivers rely on the use of larger high-voltage transistors, resulting in increased area. This area expansion compromises the overall efficiency and density of the memory array, highlighting the need for a more effective solution.

The present disclosure provides techniques for addressing the abovementioned challenges, such as to reduce the driver area with improved reliability and reduce power consumption. As disclosed herein, in some embodiments, the techniques include a driver circuit including a p-type transistor, an n-type transistor, and an inverter. The p-type transistor is coupled between a switchable voltage and a word line. The inverter includes an input configured to receive a logically inverted version of a selection signal and an output configured to provide an intermediate signal. Here, the selection signal is provided at a first logic state to assert the word line. The n-type transistor includes a gate terminal, a first source/drain terminal, and a second source/drain terminal. The gate terminal is configured to receive a control signal switching between the first supply voltage and a fourth supply voltage, the first source/drain terminal is connected to the output of the inverter, and the second source/drain terminal is connected to the word line. The techniques disclosed herein, which include a driver circuit with a p-type transistor, an n-type transistor, and an inverter, effectively address the challenges identified in traditional word line drivers. This design enables more efficient switching between the read and write voltage levels, while improving the driver's performance at both high and low voltages, reducing the need for larger high-voltage transistors. This results in a smaller driver area, improved reliability, and reduced power consumption, directly addressing the limitations of traditional designs.

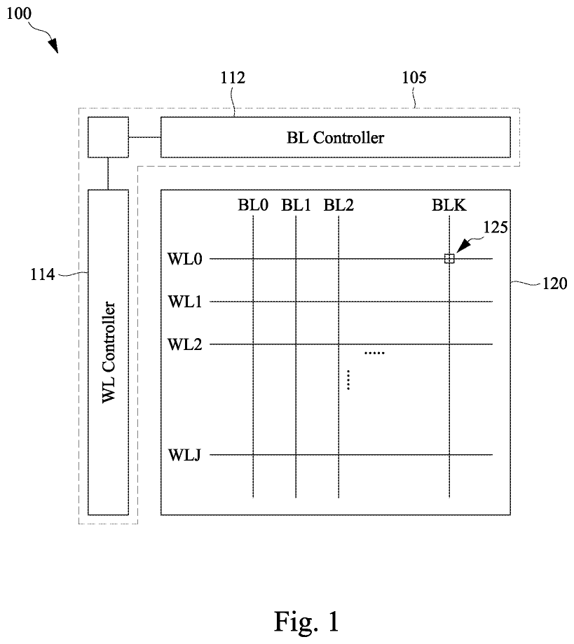

FIG. 1 illustrates a block diagram of an example memory device (or circuit) 100, in accordance with some embodiments. The memory circuit 100 includes a memory controller 105 and a memory array 120. In one aspect, the memory array 120 includes a plurality of storage circuits or memory cells 125. The memory array 120 further includes word lines WL₀, WL₁ . . . WL_{J}, each extending in a direction (e.g., X-direction) and bit lines BL₀, BL₁ . . . BL_{K}, each extending in another direction (e.g., Y-direction). The word lines WLs and the bit lines BLs may each be a conductive metal or conductive rail. In some embodiments, each memory cell 125 is coupled to a corresponding word line WL and a corresponding bit line BL, and can be operated according to voltages or currents through the corresponding word line WL and the corresponding bit line BL. In some embodiments, each bit line includes bit lines BL, BLB coupled to one or more memory cells 125 of a group of memory cells 125 disposed along the direction (e.g., Y-direction). The bit lines BL, BLB may receive and/or provide differential signals.

Each memory cell 125 may include a volatile memory cell, a non-volatile memory cell, or a combination of them. In some embodiments, the memory cells 125 each include a resistive random access memory (RRAM) cell. In some embodiments, each memory cell 125 is embodied as a static random access memory (SRAM) cell, etc. However, it should be appreciated that the memory cell 125 can be implemented as any of various other non-volatile memory cells such as, for example, a magnetoresistive random access memory (MRAM) cell, a phase-change random access memory (PCRAM) cell, an eFuse, an anti-fuse, etc., while remaining within the scope of the present disclosure. In some embodiments, the memory array 120 includes additional lines (e.g., select lines, reference lines, reference control lines, power rails, etc.).

The memory controller 105 is a hardware component that controls operations of the memory array 120. In some embodiments, the memory controller 105 includes a bit line (BL) controller 112, a word line (WL) controller 114, etc. The BL controller 112 and the WL controller 114 may be embodied as logic circuits, analog circuits, or a combination of them. In one configuration, the WL controller 114 can be a circuit that provides a voltage or current through one or more word lines WLs of the memory array 120. The BL controller 112 can be a circuit that provides or senses a voltage or current through one or more bit lines BLs of the memory array 120. The BL controller 112 may be coupled to bit lines BLs of the memory array 120, and the WL controller 114 may be coupled to word lines WLs of the memory array 120.

In some embodiments, the memory controller 105 may include a driver circuit (e.g., the word line controller 114, etc.) coupled to the memory cells 125 through the one or more word lines. The driver circuit may include a first p-type transistor coupled between a switchable voltage and the word line. The switchable voltage is selected among a first supply voltage, a second supply voltage, and a third supply voltage. The driver circuit may include an inverter having an input configured to receive a logically inverted version of a selection signal and an output configured to provide an intermediate signal. The selection signal is provided at a first logic state to assert the word line. The driver circuit may include a first n-type transistor having a gate terminal, a first source/drain terminal, and a second source/drain terminal. The gate terminal is configured to receive a control signal switching between the first supply voltage and a fourth supply voltage. The first source/drain terminal is connected to the output of the inverter, and the second source/drain terminal is connected to the word line.

In some embodiments, the driver circuit is configured to apply a voltage on the one or more word lines. The one or more word lines are connected to one or more gate terminals of one or more select transistors of one or more corresponding memory cells. The driver circuit includes a first p-type transistor coupled between a switchable voltage and the word line. The switchable voltage is selected among a first supply voltage, a second supply voltage, and a third supply voltage. The driver circuit includes a first n-type transistor having a gate terminal, a first source/drain terminal connected to the word line, and a second source/drain terminal. The gate terminal is configured to receive a control signal switching between the first supply voltage and a fourth supply voltage. The driver circuit includes a second p-type transistor and a second n-type transistor. Gate terminals of the second p-type transistor and the second n-type transistor are configured to receive a logically inverted version of a selection signal, and the selection signal is provided at a first logic state to assert the word line.

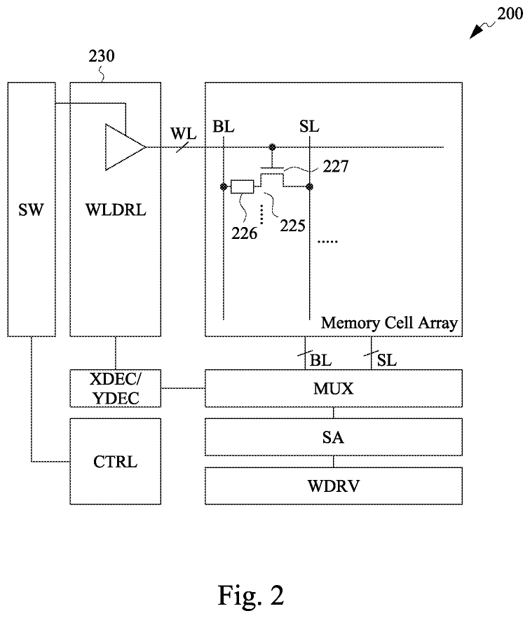

FIG. 2 illustrates a block diagram of an example memory circuit 200, in accordance with some embodiments. In some embodiments, the memory circuit 200 may be substantially similar to or incorporate features of the memory circuit 100. The memory circuit 200 is shown to include a driver circuit 230 (e.g., the word line driver WLDRV) and a resistive switching memory cell 225, including a resistive switching element 226 and a select transistor 227. It should be appreciated that the memory circuit 200 of FIG. 2 is simplified for illustrative purposes, and thus, can be implemented as any of various other configurations while remaining within the scope of the present disclosure.

While discussed in greater detail below, the driver circuit 230 can control the memory cell 225 to operate based on Table 1. Table 1 shows a non-limiting example of bias conditions of the memory cell 225. The WL voltage for READ operation can be set to a supply voltage VDD, while the WL voltage for SET/RESET operations can be set to a voltage (e.g., VWLSET, VWLRST, etc.) higher than the supply voltage VDD.

TABLE 1

| Voltage: | WL | BL | SL |
|---|---|---|---|
| Read | VDD | VBLRD | 0 |
| SET | VWLSET (>VDD) | VBLS | 0 |
| RESET | VWLRST (>VDD) | 0 | VSLRST |

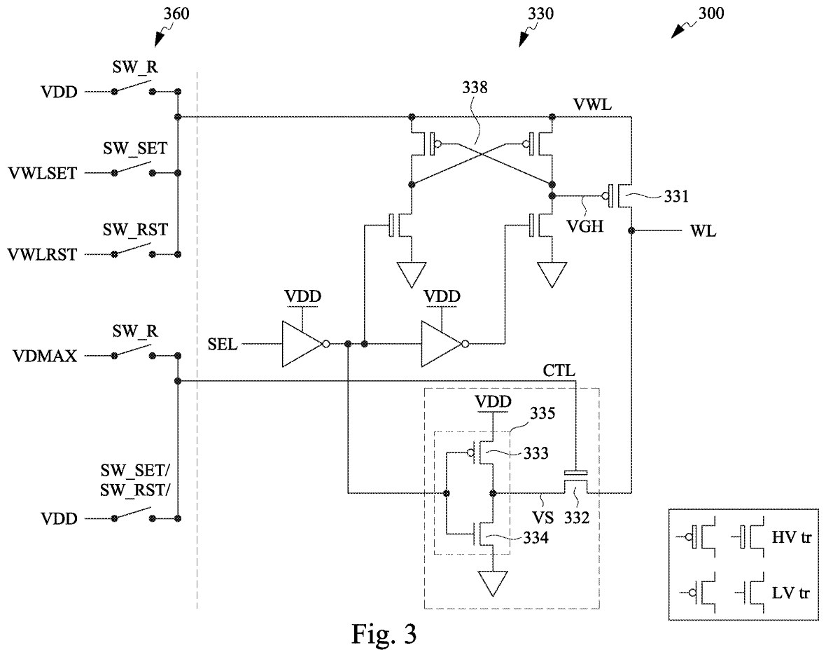

FIG. 3 illustrates a circuit diagram of an example memory circuit 300 that can be included in the memory circuit 100 of FIG. 1, in accordance with some embodiments. The memory circuit 300 includes a driver circuit 330 and a switch circuit 360. It should be appreciated that the memory circuit 300 of FIG. 3 is simplified for illustrative purposes, and thus, can be implemented as any of various other configurations while remaining within the scope of the present disclosure.

In some embodiments, the driver circuit 330 may be a word line driver circuit (e.g., as shown in FIG. 2). The driver circuit 330 can be coupled to the memory cells (e.g., the memory cells 125) through the word line WL. The driver circuit 330 can be configured to apply a voltage on the word line WL. The word line WL can be connected to a gate terminal of a select transistor of a memory cell (e.g., as shown in FIG. 2).

In some embodiments, as shown in FIG. 3, the driver circuit 330 includes a first p-type transistor 331, a first n-type transistor 332, an inverter 335 (which can include a second n-type transistor 334 and a second p-type transistor 333), cross-coupled transistors 338, etc. In some embodiments, the first p-type transistor 331 is coupled between a switchable voltage and the word line WL. The switchable voltage can be selected among a first supply voltage (e.g., VDD), a second supply voltage (e.g., VWLSET), and a third supply voltage (e.g., VWLRST). In some embodiments, the inverter 335 includes an input configured to receive a logically inverted version of a selection signal SEL. The inverter 335 can include an output configured to provide an intermediate signal VS. The selection signal SEL can be provided at a first logic state to assert the word line WL. In some embodiments, the driver circuit 330 can include the second p-type transistor 333 and the second n-type transistor 334. The gate terminals of the second p-type transistor 333 and the second n-type transistor 334 can be configured to receive the logically inverted version of the selection signal SEL. In some embodiments, the first n-type transistor 332 includes a gate terminal, a first source/drain terminal, and a second source/drain terminal. The gate terminal of the first n-type transistor 332 can be configured to receive a control signal CTL switching between the first supply voltage and a fourth supply voltage (e.g., VDMAX). The first source/drain terminal of the first n-type transistor 332 can be connected to the output of the inverter 335 (or the output from the second p-type transistor 333 and the second n-type transistor 334). The second source/drain terminal of the first n-type transistor 332 can be connected to the word line WL.

The switch circuit 360 includes a plurality of switches configured to provide a plurality of corresponding switching signals. In some embodiments, as shown in FIG. 3, the switch circuit 360 includes a switch SW_R configured to couple the first supply voltage (e.g., VDD) to the first p-type transistor 331 of the driver circuit 330, a switch SW_SET configured to couple the second supply voltage (e.g., VWLSET) to the first p-type transistor 331 of the driver circuit 330, a switch SW_RST configured to couple the third supply voltage (e.g., VWLRST) to the first p-type transistor 331 of the driver circuit 330, etc. In some embodiments, the switch SW_R can be configured to couple the fourth supply voltage (e.g., VDMAX), the second supply voltage (e.g., VWLSET), the third supply voltage (e.g., VWLRST), etc. to the gate terminal of the first n-type transistor 332. The switch SW_SET and the SW_RST can be configured to couple the first supply voltage (e.g., VDD) to the gate terminal of the first n-type transistor 332.

In some embodiments, the first p-type transistor 331 and the first n-type transistor 332 can be configured to operate with a higher voltage (e.g., than the second p-type transistor 333, the second n-type transistor 334, etc.). In some embodiments, the second p-type transistor 333 and the second n-type transistor 334 can be configured to operate with a lower voltage (e.g., than the first p-type transistor 331, the first n-type transistor 332, etc.). In some embodiments, the first p-type transistor 331 and the first n-type transistor 332 may each include a gate structure with a first length (e.g., along the X-direction) and a first width (e.g., along the Y-direction), while the second p-type transistor 333 and the second n-type transistor 334 may each include a gate structure with a second length (e.g., along the X-direction) and a second width (e.g., along the Y-direction). The first length may be substantially longer than the second length, and the first width may be substantially wider than the second width. In some embodiments, the thickness of the oxide layer and the high-k dielectric layer associated with the first p-type and n-type transistors may be configured to be greater than that of the second p-type and n-type transistors. These structural differences allow the first p-type transistor 331 and the first n-type transistor 332 to operate under a higher voltage, while the second p-type transistor 333 and the second n-type transistor 334 are configured to operate under a lower voltage. In some embodiments, the threshold voltage of the first p-type and n-type transistors may be higher than that of the second p-type and n-type transistors, enabling the first transistors to maintain stability and reliability under higher operating voltages while the second transistors optimize performance for lower voltage operations.

The switch circuit 360 can provide the control signal CTL that can be configured at various voltages. The driver circuit 330 can be configured to receive the control signal CTL and perform various operations (e.g., read, write, etc.) based on the control signal CTL. In some embodiments, the control signal CTL can be configured at the first supply voltage (e.g., VDD) when at least one of the memory cells is selected to be written. For example, in response to a memory cell being selected to be written, the switch SW_R can be opened and the switch SW_SET (and/or the switch SW_RST) can be closed to couple the first supply voltage (e.g., VDD) to the control signal CTL. In some embodiments, the control signal CTL can be configured at the fourth supply voltage (e.g., VDMAX) when at least one of the memory cells is selected to be read. For example, in response to a memory cell being selected to be read, the switch SW_SET (and/or the switch SW_RST) can be opened and the switch SW_R can be closed to couple the fourth supply voltage (e.g., VDMAX) to the control signal CTL. In some embodiments, the fourth supply voltage (e.g., VDMAX) is higher than the first supply voltage (e.g., VDD).

The switch circuit 360 can provide the switchable voltage selected among the first supply voltage (e.g., VDD), the second supply voltage (e.g., VWLSET), and the third supply voltage (e.g., VWLRST). For example, the switch circuit 360 can be configured to provide the switchable voltage based on switching operations of the switch SW_R, the switch SW_SET, the switch SW_RST, etc. The driver circuit 330 can receive the switchable voltage and perform various operations (e.g., read, write, etc.) based on the switchable voltage. In some embodiments, the switchable voltage can be configured at the second supply voltage (e.g., VWLSET) or the third supply voltage (e.g., VWLRST) when at least one of the memory cells is selected to be written. For example, in response to a memory cell selected to be written, the switch SW_R can be opened and the switch SW_SET or the switch SW_RST can be closed to couple the second supply voltage (e.g., VWLSET) or the third supply voltage (e.g., VWLRST) to the driver circuit 330. In some embodiments, the switchable voltage can be configured at the first supply voltage (e.g., VDD) when at least one of the memory cells is selected to be read. For example, in response to a memory cell selected to be read, the switch SW_SET and the switch SW_RST can be opened and the switch SW_R can be closed to couple the first supply voltage (e.g., VDD) to the driver circuit 330. In some embodiments, the third supply voltage (e.g., VWLRST) is higher than the second supply voltage (e.g., VWLSET), and the second supply voltage (e.g., VWLSET) is higher than the first supply voltage (e.g., VDD). In some embodiments, during the read operation, the word line WL can be pulled up by the second p-type transistor 333 and the first p-type transistor 331, while the intermediate signal VS can be set to the supply voltage VDD via the second p-type transistor 333. During the write operation, the word line WL can be pulled up by the first p-type transistor 331, while the intermediate signal VS can be set to the supply voltage VDD via the second p-type transistor 333. The first n-type transistor 332 can be substantially turned off with its gate coupled to the control signal CTL being at the supply voltage VDD, as the voltage between the gate terminal (e.g., VDD) and the source/drain terminal (e.g., VDD) is smaller than the threshold voltage.

In some embodiments, during the read operation, the gate terminal of the first n-type transistor 332 can be coupled to the fourth supply voltage (e.g., VDMAX), which can be higher than the first supply voltage (e.g., VDD), thereby ensuring that the drivability and high-speed pull up/down operations. During the write operation, the gate terminal of the first n-type transistor 332 can be coupled to the first supply voltage (e.g., VDD), thereby suppressing the intermediate signal VS (e.g., the node for the intermediate signal VS does not exceed the first supply voltage (e.g., VDD) as the gate terminal of the first n-type transistor 332 is coupled to the first supply voltage (e.g., VDD)). The memory circuits as disclosed herein can thereby allow for high-speed operations during read/write operations.

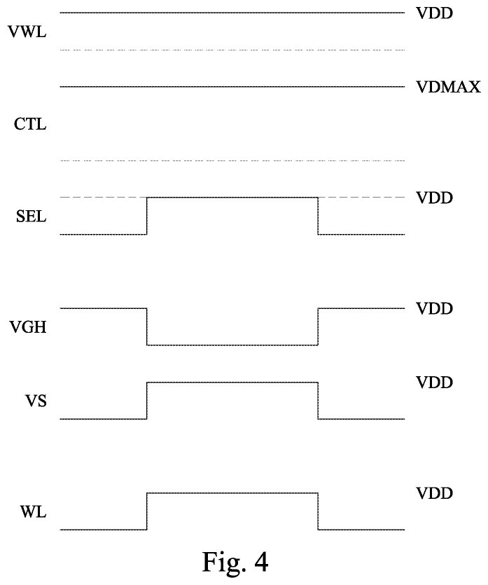

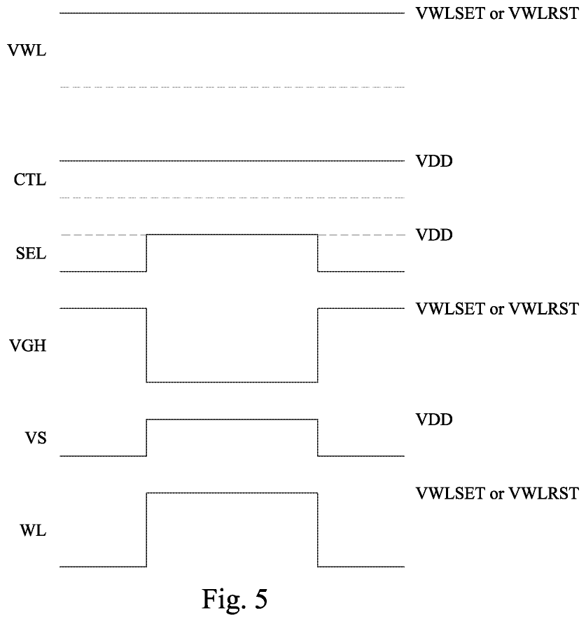

Table 2 shows a non-limiting example of bias conditions of the memory circuit 300. FIG. 4 and FIG. 5 illustrate example waveforms associated with a memory circuit (e.g., the memory circuits 100, 200, 300, etc.), in accordance with some embodiments. In some embodiments, the waveforms shown in FIG. 4 are associated with the read operation of the memory circuit 300, and the waveforms shown in FIG. 5 are associated with the write operation of the memory circuit 300. It should be appreciated that the waveforms shown in FIG. 4 and FIG. 5 are simplified for illustrative purposes, and thus, can be implemented as any of various other forms while remaining within the scope of the present disclosure.

TABLE 2

| WL status | Operation | VWL | CTL | WL |
|---|---|---|---|---|
| Select WL | Read | VDD | VDMAX | VDD |
| (e.g., SEL = | SET | VWLSET | VDD | VWLSET |
| VDD) | RESET | VWLRST | VDD | VWLRST |
| Unselect WL | Read | VDD | VDMAX | 0 V |
| (e.g., SEL = | SET | VWLSET | VDD | 0 V |
| 0 V) | RESET | VWLRST | VDD | 0 V |

In response to a memory cell being selected (e.g., WL status being “Select WL”) with a selection signal SEL (e.g., the selection signal at the first supply voltage, VDD), the memory circuit 300 can be configured to perform read operation (e.g., “Read”) and write operation (e.g., “SET,” “RESET,” etc.). During the read operation, the switch circuit 360 can be configured to provide the switchable voltage (e.g., VWL) at the first supply voltage (e.g., VDD), and provide the control signal CTL at the fourth supply voltage (e.g., VDMAX), thereby allowing the driver circuit 330 to assert the word line WL at the first supply voltage (e.g., VDD). During the write operation, the switch circuit 360 can be configured to provide the switchable voltage (e.g., VWL) at the second supply voltage (e.g., VWLSET) or at the third supply voltage (e.g., VWLRST), and provide the control signal CTL at the first supply voltage (e.g., VDD), thereby allowing the driver circuit 330 to assert the word line WL at the second supply voltage (e.g., VWLSET) or at the third supply voltage (e.g., VWLRST).

In response to a memory cell being not selected (e.g., WL status being “Unselect WL”) with a selection signal SEL being at 0 V, the memory circuit 300 can be configured to not assert the word line WL. In response to the switchable voltage (e.g., VWL) at the first supply voltage (e.g., VDD), the control signal CTL can be configured at the fourth supply voltage (e.g., VDMAX), thereby allowing the driver circuit 330 to not assert the word line WL (e.g., 0 V). In response to the switchable voltage (e.g., VWL) at the second supply voltage (e.g., VWLSET) or at the third supply voltage (e.g., VWLRST), the control signal CTL can be configured at the first supply voltage (e.g., VDD), thereby allowing the driver circuit 330 to not assert the word line WL (e.g., 0 V).

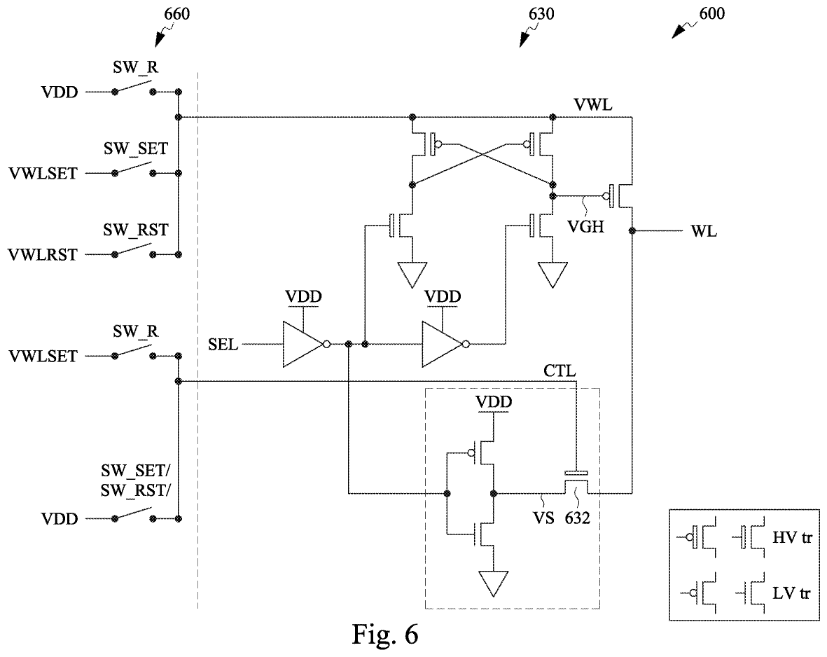

FIG. 6 illustrates a circuit diagram of an example memory circuit 600 that can be included in the memory circuit 100 of FIG. 1, in accordance with some embodiments. The memory circuit 600 includes a driver circuit 630 and a switch circuit 660. It should be appreciated that the memory circuit 600 of FIG. 6 is simplified for illustrative purposes, and thus, can be implemented as any of various other configurations while remaining within the scope of the present disclosure.

In some embodiments, the memory circuit 600 may be similar to or incorporate features of the memory circuit 300. For example, in the memory circuit 600, the control signal CTL can be configured to switch between the first supply voltage (e.g., VDD) and the second supply voltage (e.g., VWLSET) alternatively as opposed to the memory circuit 300. In some embodiments, the control signal CTL can be configured to switch between the first supply voltage (e.g., VDD) and the second supply voltage (e.g., VWLSET) when the second supply voltage (e.g., VWLSET) is higher than the third supply voltage (e.g., VWLRST). In some embodiments, the control signal CTL can be configured at the first supply voltage (e.g., VDD) when at least one of the memory cells is selected to be written. For example, in response to a memory cell being selected to be written, the switch SW_R can be opened and the switch SW_SET (and/or the switch SW_RST) can be closed to couple the first supply voltage (e.g., VDD) to the control signal CTL. In some embodiments, the control signal CTL can be configured at the second supply voltage (e.g., VWLSET) when at least one of the memory cells is selected to be read. For example, in response to a memory cell being selected to be read, the switch SW_SET (and/or the switch SW_RST) can be opened and the switch SW_R can be closed to couple the second supply voltage (e.g., VWLSET) to the control signal CTL. In some embodiments, the second supply voltage (e.g., VWLSET) is higher than the first supply voltage (e.g., VDD).

In some embodiments, the gate terminal of the first n-type transistor 632 can be configured to receive the control signal CTL switching between the first supply voltage and the second supply voltage (e.g., VWLSET). In some embodiments, during the read operation, the gate terminal of the first n-type transistor 632 can be coupled to the second supply voltage (e.g., VWLSET), which can be higher than the first supply voltage (e.g., VDD), thereby ensuring that the drivability and high-speed pull up/down operations. During the write operation, the gate terminal of the first n-type transistor 632 can be coupled to the first supply voltage (e.g., VDD), thereby suppressing the intermediate signal VS (e.g., the node for the intermediate signal VS does not exceed the first supply voltage (e.g., VDD) as the gate terminal of the first n-type transistor 632 is coupled to the first supply voltage (e.g., VDD)). The memory circuits as disclosed herein can thereby allow for high-speed operations during read/write operations.

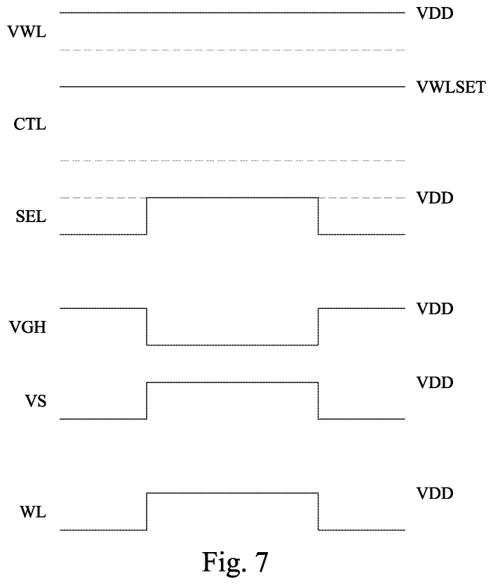

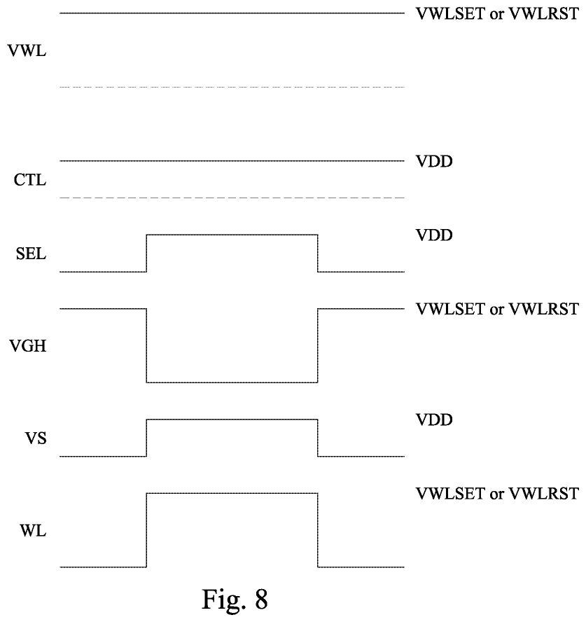

Table 3 shows a non-limiting example of bias conditions of the memory circuit 600. FIG. 7 and FIG. 8 illustrate example waveforms associated with a memory circuit (e.g., the memory circuits 100, 200, 600, etc.), in accordance with some embodiments. In some embodiments, the waveforms shown in FIG. 7 are associated with the read operation of the memory circuit 600, and the waveforms shown in FIG. 8 are associated with the write operation of the memory circuit 600. It should be appreciated that the waveforms shown in FIG. 7 and FIG. 8 are simplified for illustrative purposes, and thus, can be implemented as any of various other forms while remaining within the scope of the present disclosure.

TABLE 3

| WL status | Operation | VWL | CTL | WL |
|---|---|---|---|---|
| Select WL | Read | VDD | VWLSET | VDD |
| (e.g., SEL = | SET | VWLSET | VDD | VWLSET |
| VDD) | RESET | VWLRST | VDD | VWLRST |
| Unselect WL | Read | VDD | VWLSET | 0 V |
| (e.g., SEL = | SET | VWLSET | VDD | 0 V |
| 0 V) | RESET | VWLRST | VDD | 0 V |

In response to a memory cell being selected (e.g., WL status being “Select WL”) with a selection signal SEL (e.g., the selection signal at the first supply voltage, VDD), the memory circuit 600 can be configured to perform read operation (e.g., “Read”) and write operation (e.g., “SET,” “RESET,” etc.). During the read operation, the switch circuit 660 can be configured to provide the switchable voltage (e.g., VWL) at the first supply voltage (e.g., VDD), and provide the control signal CTL at the second supply voltage (e.g., VWLSET), thereby allowing the driver circuit 630 to assert the word line WL at the first supply voltage (e.g., VDD). During the write operation, the switch circuit 660 can be configured to provide the switchable voltage (e.g., VWL) at the second supply voltage (e.g., VWLSET) or at the third supply voltage (e.g., VWLRST), and provide the control signal CTL at the first supply voltage (e.g., VDD), thereby allowing the driver circuit 630 to assert the word line WL at the second supply voltage (e.g., VWLSET) or at the third supply voltage (e.g., VWLRST).

In response to a memory cell being not selected (e.g., WL status being “Unselect WL”) with a selection signal SEL being at 0 V, the memory circuit 600 can be configured to not assert the word line WL. In response to the switchable voltage (e.g., VWL) at the first supply voltage (e.g., VDD), the control signal CTL can be configured at the second supply voltage (e.g., VWLSET), thereby allowing the driver circuit 630 to not assert the word line WL (e.g., 0 V). In response to the switchable voltage (e.g., VWL) at the second supply voltage (e.g., VWLSET) or at the third supply voltage (e.g., VWLRST), the control signal CTL can be configured at the first supply voltage (e.g., VDD), thereby allowing the driver circuit 630 to not assert the word line WL (e.g., 0 V).

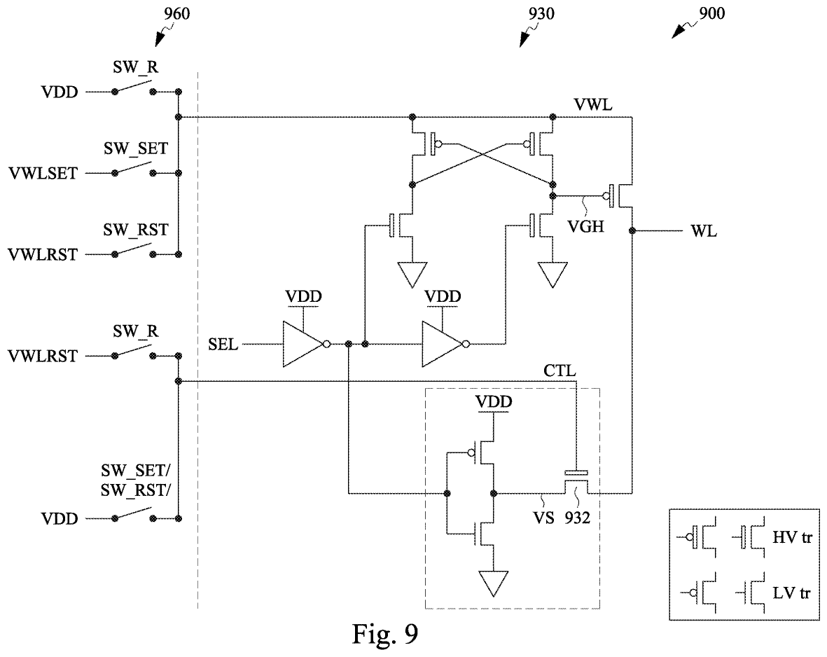

FIG. 9 illustrates a circuit diagram of an example memory circuit 900 that can be included in the memory circuit 100 of FIG. 1, in accordance with some embodiments. The memory circuit 900 includes a driver circuit 930 and a switch circuit 960. It should be appreciated that the memory circuit 900 of FIG. 9 is simplified for illustrative purposes, and thus, can be implemented as any of various other configurations while remaining within the scope of the present disclosure.

In some embodiments, the memory circuit 900 may be similar to or incorporate features of the memory circuit 300. For example, in the memory circuit 900, the control signal CTL can be configured to switch between the first supply voltage (e.g., VDD) and the third supply voltage (e.g., VWLRST) alternatively as opposed to the memory circuit 300. In some embodiments, the control signal CTL can be configured to switch between the first supply voltage (e.g., VDD) and the third supply voltage (e.g., VWLRST) when the third supply voltage (e.g., VWLRST) is higher than the second supply voltage (e.g., VWLSET). In some embodiments, the control signal CTL can be configured at the first supply voltage (e.g., VDD) when at least one of the memory cells is selected to be written. For example, in response to a memory cell being selected to be written, the switch SW_R can be opened and the switch SW_SET (and/or the switch SW_RST) can be closed to couple the first supply voltage (e.g., VDD) to the control signal CTL. In some embodiments, the control signal CTL can be configured at the third supply voltage (e.g., VWLRST) when at least one of the memory cells is selected to be read. For example, in response to a memory cell being selected to be read, the switch SW_SET (and/or the switch SW_RST) can be opened and the switch SW_R can be closed to couple the third supply voltage (e.g., VWLRST) to the control signal CTL. In some embodiments, the third supply voltage (e.g., VWLRST) is higher than the first supply voltage (e.g., VDD).

In some embodiments, the gate terminal of the first n-type transistor 932 can be configured to receive the control signal CTL switching between the first supply voltage and the third supply voltage (e.g., VWLRST). In some embodiments, during the read operation, the gate terminal of the first n-type transistor 932 can be coupled to the third supply voltage (e.g., VWLRST), which can be higher than the first supply voltage (e.g., VDD), thereby ensuring that the drivability and high-speed pull up/down operations. During the write operation, the gate terminal of the first n-type transistor 932 can be coupled to the first supply voltage (e.g., VDD), thereby suppressing the intermediate signal VS (e.g., the node for the intermediate signal VS does not exceed the first supply voltage (e.g., VDD) as the gate terminal of the first n-type transistor 932 is coupled to the first supply voltage (e.g., VDD)). The memory circuits as disclosed herein can thereby allow for high-speed operations during read/write operations.

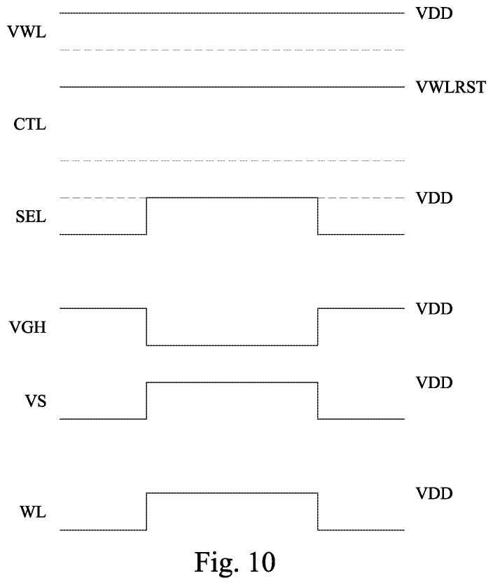

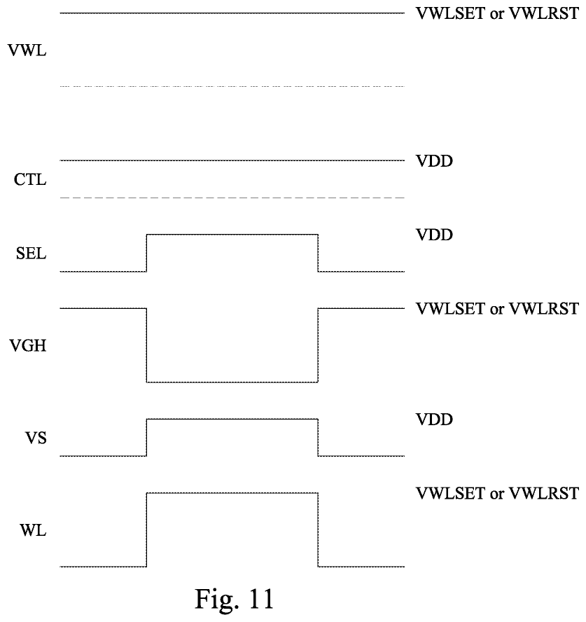

Table 4 shows a non-limiting example of bias conditions of the memory circuit 900. FIG. 10 and FIG. 11 illustrate example waveforms associated with a memory circuit (e.g., the memory circuits 100, 200, 900, etc.), in accordance with some embodiments. In some embodiments, the waveforms shown in FIG. 10 are associated with the read operation of the memory circuit 900, and the waveforms shown in FIG. 11 are associated with the write operation of the memory circuit 900. It should be appreciated that the waveforms shown in FIG. 10 and FIG. 11 are simplified for illustrative purposes, and thus, can be implemented as any of various other forms while remaining within the scope of the present disclosure.

TABLE 4

| WL status | Operation | VWL | CTL | WL |
|---|---|---|---|---|
| Select WL | Read | VDD | VWLRST | VDD |
| (e.g., SEL = | SET | VWLSET | VDD | VWLSET |
| VDD) | RESET | VWLRST | VDD | VWLRST |
| Unselect WL | Read | VDD | VWLRST | 0 V |
| (e.g., SEL = | SET | VWLSET | VDD | 0 V |
| 0 V) | RESET | VWLRST | VDD | 0 V |

In response to a memory cell being selected (e.g., WL status being “Select WL”) with a selection signal SEL (e.g., the selection signal at the first supply voltage, VDD), the memory circuit 900 can be configured to perform read operation (e.g., “Read”) and write operation (e.g., “SET,” “RESET,” etc.). During the read operation, the switch circuit 960 can be configured to provide the switchable voltage (e.g., VWL) at the first supply voltage (e.g., VDD), and provide the control signal CTL at the third supply voltage (e.g., VWLRST), thereby allowing the driver circuit 930 to assert the word line WL at the first supply voltage (e.g., VDD). During the write operation, the switch circuit 960 can be configured to provide the switchable voltage (e.g., VWL) at the second supply voltage (e.g., VWLSET) or at the third supply voltage (e.g., VWLRST), and provide the control signal CTL at the first supply voltage (e.g., VDD), thereby allowing the driver circuit 930 to assert the word line WL at the second supply voltage (e.g., VWLSET) or at the third supply voltage (e.g., VWLRST).

In response to a memory cell being not selected (e.g., WL status being “Unselect WL”) with a selection signal SEL being at 0 V, the memory circuit 900 can be configured to not assert the word line WL. In response to the switchable voltage (e.g., VWL) at the first supply voltage (e.g., VDD), the control signal CTL can be configured at the third supply voltage (e.g., VWLRST), thereby allowing the driver circuit 930 to not assert the word line WL (e.g., 0 V). In response to the switchable voltage (e.g., VWL) at the second supply voltage (e.g., VWLSET) or at the third supply voltage (e.g., VWLRST), the control signal CTL can be configured at the first supply voltage (e.g., VDD), thereby allowing the driver circuit 930 to not assert the word line WL (e.g., 0 V).

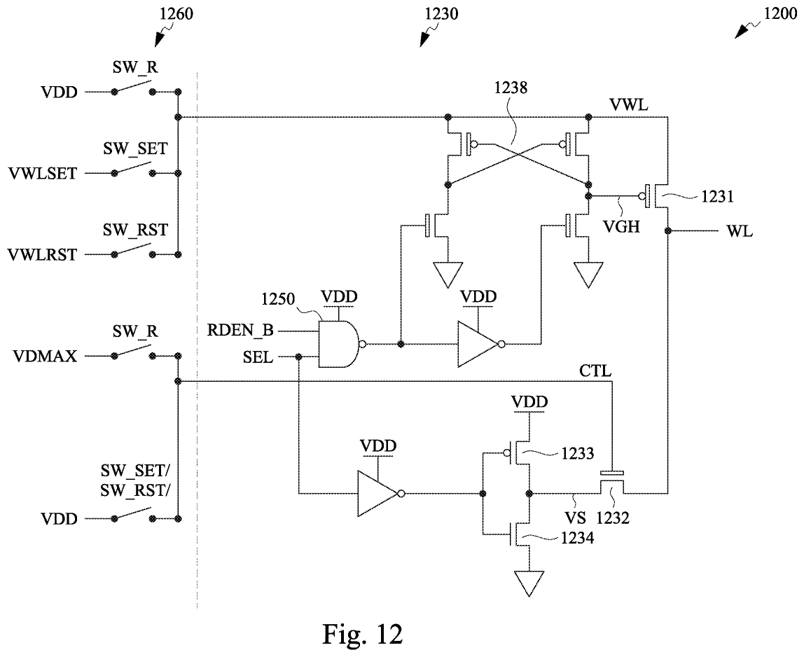

FIG. 12 illustrates a circuit diagram of an example memory circuit 1200 that can be included in the memory circuit 100 of FIG. 1, in accordance with some embodiments. It should be appreciated that the memory circuit 1200 of FIG. 12 is simplified for illustrative purposes, and thus, can be implemented as any of various other configurations while remaining within the scope of the present disclosure.

In some embodiments, the memory circuit 1200 can be substantially similar to or incorporate features of the memory circuits 100, 200, 300, 600, 900, etc. For example, the memory circuit 1200 includes a driver circuit 1230 and a switch circuit 1260. The driver circuit 1230 includes a first p-type transistor 1231, a first n-type transistor 1232, a second p-type transistor 1233, a second n-type transistor 1234, cross-coupled transistors 1238, etc. The memory circuit 1200 additionally includes a logic gate 1250, as opposed to the memory circuits 300, 600, 900, etc.

In some embodiments, the cross-coupled transistors 1238 can be coupled to a gate of the first p-type transistor 1231. In some embodiments, the logic gate 1250 can be coupled between the selection signal SEL and the cross-coupled transistors 1238. For example, as shown, the logic gate 1250 can be coupled to the selection signal SEL through a first input and a read enable signal RDEN_B through a second input, while the logic gate 1250 can provide an output to the cross-coupled transistors 1238. In some embodiments, an inverted version of the read enable signal RDEN_B can be set to logic high during the write operation, and can be set to logic low during the read operation. Although shown as a NAND gate, the logic gate 1250 can be or include any logic gates or combination thereof to receive various inputs and perform various logic operations.

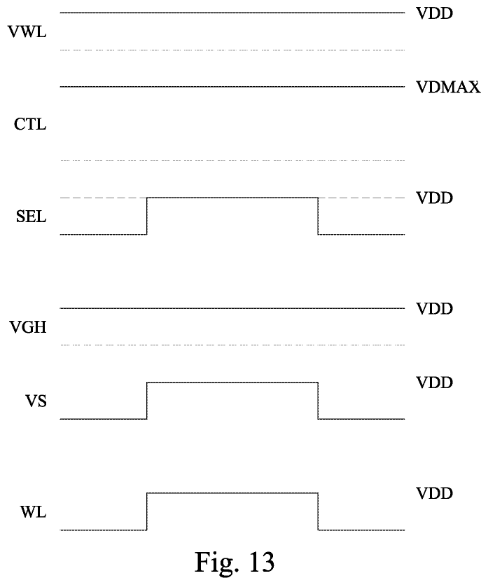

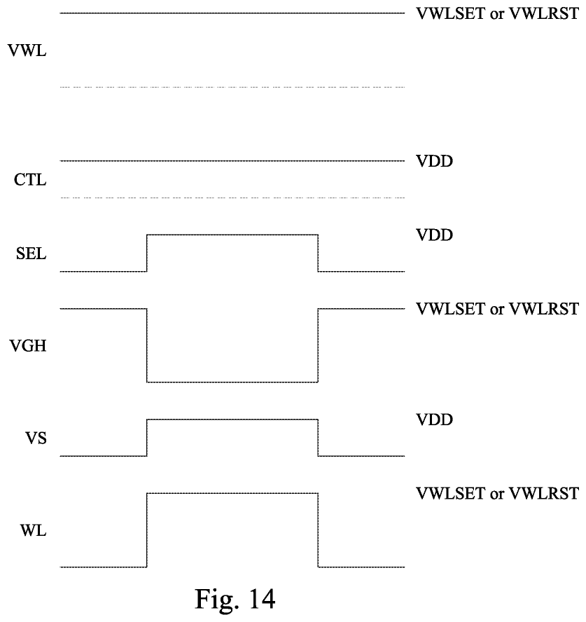

FIG. 13 and FIG. 14 illustrate example waveforms associated with a memory circuit (e.g., the memory circuits 100, 200, 1200, etc.), in accordance with some embodiments. In some embodiments, the waveforms shown in FIG. 13 are associated with the read operation of the memory circuit 1200, and the waveforms shown in FIG. 14 are associated with the write operation of the memory circuit 1200. It should be appreciated that the waveforms shown in FIG. 13 and FIG. 14 are simplified for illustrative purposes, and thus, can be implemented as any of various other forms while remaining within the scope of the present disclosure. As shown in FIG. 13, in some embodiments, in which the logic gate 1250 is included in the memory circuit 1200, a signal VGH does not toggle during the read operation.

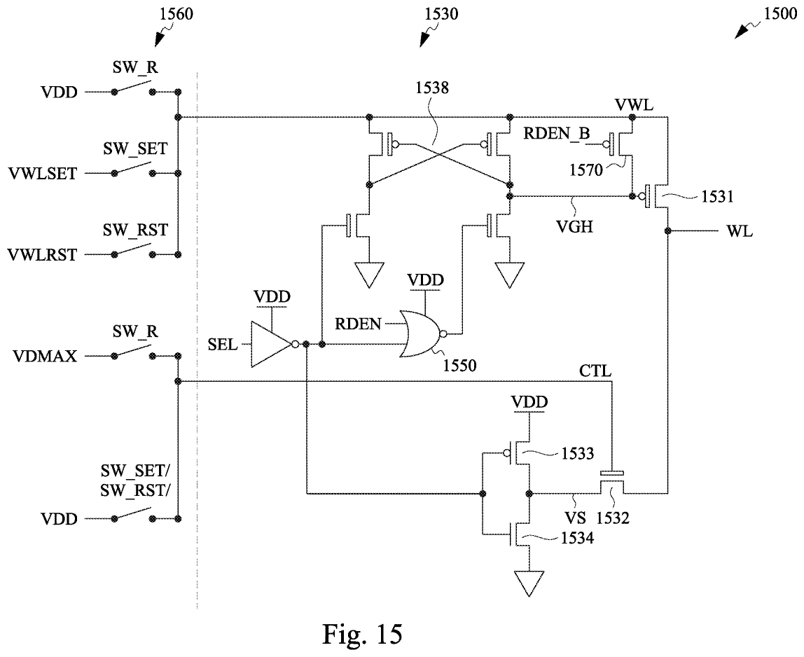

FIG. 15 illustrates a circuit diagram of an example memory circuit 1500 that can be included in the memory circuit 100 of FIG. 1, in accordance with some embodiments. It should be appreciated that the memory circuit 1500 of FIG. 15 is simplified for illustrative purposes, and thus, can be implemented as any of various other configurations while remaining within the scope of the present disclosure.

In some embodiments, the memory circuit 1500 can be substantially similar to or incorporate features of the memory circuits 100, 200, 300, 600, 900, 1200, etc. For example, the memory circuit 1500 includes a driver circuit 1530 and a switch circuit 1560. The driver circuit 1530 includes a first p-type transistor 1531, a first n-type transistor 1532, a second p-type transistor 1533, a second n-type transistor 1534, cross-coupled transistors 1538, etc. The memory circuit 1500 alternatively includes a logic gate 1550, as opposed to the memory circuit 1200.

In some embodiments, the logic gate 1550 can be configured to receive a logically inverted version of the selection signal SEL and provide an output to the cross-coupled transistors 1538. For example, the logic gate 1550 can be configured to receive the logically inverted version of the selection signal SEL through a first input via an inverter and receive the read enable signal RDEN through a second input. The logic gate 1550 can provide an output to the cross-coupled transistors 1538.

In some embodiments, the driver circuit 1530 can include a third p-type transistor 1570. The third p-type transistor 1570 can include a first source/drain terminal coupled to the gate terminal of the first p-type transistor 1231 and a second source/drain terminal coupled to the source/drain of the first p-type transistor 1531. In some embodiments, the gate terminal of the third p-type transistor 1570 can be coupled to an inverted version of the read enable signal RDEN_B. As with the memory circuit 1200 (e.g., as shown in FIG. 13), in some embodiments, the signal VGH does not toggle during the read operation with the logic gate 1550, the third p-type transistor 1570, etc. For example, the inverted version of the read enable signal RDEN_B can be set to logic high during the write operation and set to logic low during the read operation. The read enable signal RDEN can be set to logic low during the write operation and set to high during the read operation. Although shown as a NOR gate, the logic gate 1550 can be or include any logic gates or combination thereof to receive various inputs and perform various logic operations.

As disclosed herein, the memory circuits are discussed, including the driver circuits and the switch circuits. Although the driver circuits (e.g., the driver circuits 300, 600, 900, etc.) are shown and discussed to include transistors in various manners (e.g., types, arrangements, etc.), in some embodiments, without relying solely on such a manner, the memory circuits, or part thereof (e.g., the switch circuits) can be configured to assert the word line WL at the first supply voltage (e.g., VDD) during the read operation and at the second supply voltage (e.g., VWLSET) or at the third supply voltage (e.g., VWLRST) during the write operation.

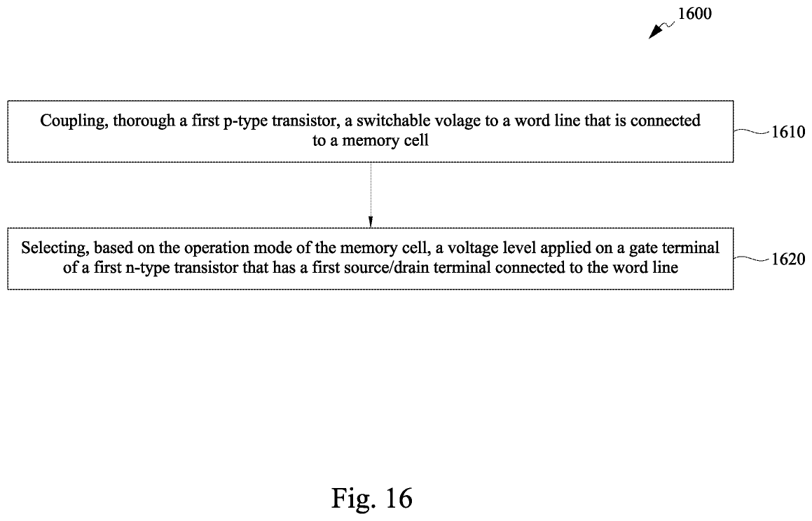

FIG. 16 illustrates a flow chart of an example method 1600 for operating a memory circuit, in accordance with some embodiments. In some embodiments, the method 1600 can be performed to operate a memory circuit (e.g., the memory circuits 100, 200, 300, etc.), and thus, some of the references used above may be reused in the following discussion of the method 1600. It is noted that the method 1600 is merely an example and is not intended to limit the present disclosure. Accordingly, it is understood that additional operations may be provided before, during, and after the method 1600 of FIG. 16, and that some other operations may only be briefly described herein.

In a brief overview, the method 1600 can begin with operation 1610 of coupling, through a first p-type transistor, a switchable voltage to a word line that is connected to a memory cell. The method 1600 can continue to operation 1620 of selecting, based on the operation mode of the memory cell, a voltage level applied on a gate terminal of a first n-type transistor that has a first source/drain terminal connected to the word line.

At operation 1610, the method 1600 includes coupling, through a first p-type transistor (e.g., the first p-type transistor 331), a switchable voltage to a word line (e.g., the word line WL of FIG. 3) that is connected to a memory cell (e.g., the memory cell 125). The switchable voltage can be selected among a first supply voltage (e.g., VDD), a second supply voltage (e.g., VWLSET), and a third supply voltage (e.g., VWLRST) based on an operation mode of the memory cell.

In some embodiments, the method 1600 includes receiving, through an inverter (e.g., the inverter 335) including a second p-type transistor (e.g., the second p-type transistor 333) and a second n-type transistor (e.g., the second n-type transistor 334), a selection signal (e.g., the selection signal SEL of FIG. 3) configured at a certain logic state to assert the word line. In some embodiments, the method 1600 includes providing, to a second source/drain terminal of the first n-type transistor, an intermediate signal (e.g., the intermediate signal VS of FIG. 3) based on the selection signal.

In some embodiments, the method 1600 includes configuring the first p-type transistor and first n-type transistor to operate with a higher voltage (e.g., than the second p-type transistor 333, the second n-type transistor 334, etc.). In some embodiments, the method 1600 includes configuring he second p-type transistor and second n-type transistor to operate with a lower voltage (e.g., than the first p-type transistor 331, the first n-type transistor 332, etc.).

At operation 1620, the method 1600 includes selecting, based on the operation mode of the memory cell, a voltage level applied on a gate terminal of a first n-type transistor (e.g., the first n-type transistor 332) that has a first source/drain terminal connected to the word line. The voltage level can be selected to be equal to the first supply voltage or a fourth supply voltage (e.g., VDMAX).

In one aspect of the present disclosure, a memory circuit is disclosed. The memory circuit includes a memory array including a plurality of memory cells coupled to a word line and a driver circuit coupled to the plurality of memory cells through the word line. The driver circuit includes a first p-type transistor coupled between a switchable voltage and the word line, wherein the switchable voltage is selected among a first supply voltage, a second supply voltage, and a third supply voltage, an inverter having an input configured to receive a logically inverted version of a selection signal and an output configured to provide an intermediate signal, wherein the selection signal is provided at a first logic state to assert the word line, and a first n-type transistor having a gate terminal, a first source/drain terminal, and a second source/drain terminal, wherein the gate terminal is configured to receive a control signal switching between the first supply voltage and a fourth supply voltage, the first source/drain terminal is connected to the output of the inverter, and the second source/drain terminal is connected to the word line.

In another aspect of the present disclosure, a memory circuit is disclosed. The memory circuit includes a driver circuit configured to apply a voltage on a word line, wherein the word line is connected to a gate terminal of a select transistor of a memory cell. The driver circuit includes a first p-type transistor coupled between a switchable voltage and the word line, wherein the switchable voltage is selected among a first supply voltage, a second supply voltage, and a third supply voltage, a first n-type transistor having a gate terminal, a first source/drain terminal connected to the word line, and a second source/drain terminal, wherein the gate terminal is configured to receive a control signal switching between the first supply voltage and a fourth supply voltage, and a second p-type transistor and a second n-type transistor, wherein gate terminals of the second p-type transistor and the second n-type transistor are configured to receive a logically inverted version of a selection signal, and the selection signal is provided at a first logic state to assert the word line.

In yet another aspect of the present disclosure, a method for operating a memory circuit is disclosed. The method includes coupling, through a first p-type transistor, a switchable voltage to a word line that is connected to a memory cell, wherein the switchable voltage is selected among a first supply voltage, a second supply voltage, and a third supply voltage based on an operation mode of the memory cell, and selecting, based on the operation mode of the memory cell, a voltage level applied on a gate terminal of a first n-type transistor that has a first source/drain terminal connected to the word line, wherein the voltage level is selected to be equal to the first supply voltage or a fourth supply voltage.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory circuit, comprising:
a memory array including a plurality of memory cells; and
a driver circuit coupled to the plurality of memory cells;
wherein the driver circuit comprises:
a first transistor coupled to a first voltage selected among a first set of a plurality of supply voltages;
an inverter configured to provide an intermediate signal based on a selection signal provided at a first logic state to drive at least one of the plurality of memory cells; and
a second transistor configured to receive a control signal switching between a second set of the plurality of supply voltages and connected to the inverter.

2. The memory circuit of claim 1, wherein the inverter includes a third transistor and a fourth transistor, and wherein the first transistor and second transistor are configured to operate with a higher voltage while the third transistor and fourth transistor are configured to operate with a lower voltage.

3. The memory circuit of claim 1, wherein the second set of the plurality of supply voltages includes supply voltages included in the first set of the plurality of supply voltages and one or more additional supply voltages.

4. The memory circuit of claim 1, wherein the control signal is configured at a first supply voltage, of the first set, and at a second supply voltage, of the second set, when the at least one of the plurality of memory cells is selected to be written and when the at least one of the plurality of memory cells is selected to be read, respectively, wherein the second supply voltage is higher than the first supply voltage.

5. The memory circuit of claim 1, wherein the first voltage is configured at a first supply voltage of the first set when the at least one of the plurality of memory cells is selected to be written, and configured at a second supply voltage of the first set when the at least one of the plurality of memory cells is selected to be read.

6. The memory circuit of claim 5, wherein the first supply voltage is higher than the second supply voltage.

7. The memory circuit of claim 1, wherein the plurality of memory cells each include a resistive random access memory (RRAM) cell.

8. The memory circuit of claim 1, further comprising cross-coupled transistors coupled to the first transistor, and a logic gate coupled between the selection signal and the cross-coupled transistors.

9. The memory circuit of claim 8, wherein the logic gate is configured to receive a logically inverted version of the selection signal and provide an output to the cross-coupled transistors.

10. The memory circuit of claim 1, further comprising a fifth transistor having a first source/drain terminal coupled to a gate terminal of the first transistor and a second source/drain terminal coupled to a source/drain of the first transistor.

11. A memory circuit, comprising:
a driver circuit configured to apply a voltage to drive a memory cell through a gate terminal of a select transistor of a memory cell;
wherein the driver circuit comprises:
a first transistor coupled to a switchable voltage, wherein the switchable voltage is selected among a first set of a plurality of supply voltages;
a second transistor having a gate terminal configured to receive a control signal switching between one of the first set of the plurality of supply voltages and one of a second set of the plurality of supply voltages; and
a third transistor and a fourth transistor, wherein gate terminals of the third transistor and the fourth transistor are configured to receive a logically inverted version of a selection signal, and the selection signal is provided at a first logic state to drive the memory cell.

12. The memory circuit of claim 11, wherein the second transistor is connected to the third transistor and the fourth transistor, and the fourth transistor and the third transistor are configured to provide an intermediate signal to a source/drain terminal of the second transistor.

13. The memory circuit of claim 11, wherein the first transistor and second transistor are configured to operate with a higher voltage while the third transistor and fourth transistor are configured to operate with a lower voltage.

14. The memory circuit of claim 11, wherein the control signal is configured at a first supply voltage of the first set and at a second supply voltage of the second set when the memory cell is selected to be written and when the memory cell is selected to be read, respectively, and wherein the second voltage is higher than the first supply voltage.

15. The memory circuit of claim 11, wherein the switchable voltage is configured at a first supply voltage of the first set when the memory cell is selected to be read, and configured at a second supply voltage when the memory cell is selected to be written, and wherein the second supply voltage is higher than the first supply voltage.

16. The memory circuit of claim 11, wherein the memory cell includes a resistive random access memory (RRAM) cell.

17. The memory circuit of claim 11, further comprising cross-coupled transistors coupled to a gate of the first transistor, and a logic gate coupled between the selection signal and the cross-coupled transistors, wherein the logic gate is configured to receive a logically inverted version of the selection signal and provide an output to the cross-coupled transistors.

18. A method for operating a memory circuit, comprising:
coupling, through a first transistor, a first voltage to drive a memory cell, the first voltage selected among a plurality of supply voltages based on an operation mode of the memory cell; and
selecting, based on the operation mode of the memory cell, a voltage level applied on a gate terminal of a second transistor, wherein the voltage level is selected to be equal to one of a first set of the plurality of supply voltages or one of a second set of the plurality of supply voltages.

19. The method of claim 18, further comprising:
receiving, through an inverter including a third transistor and a fourth transistor, a selection signal configured at a certain logic state; and
providing, to a source/drain terminal of the second transistor, an intermediate signal based on the selection signal.

20. The method of claim 19, wherein the first transistor and second transistor are configured to operate with a higher voltage while the third transistor and fourth transistor are configured to operate with a lower voltage.
